(19) United States
(12) Patent Application Publication
(10) Pub. No.: US 2026/0040609 A1
(43) Pub. Date: Feb. 5, 2026

(54) LDMOS AND FABRICATING METHOD OF THE SAME

(71) Applicant: UNITED MICROELECTRONICS CORP., Hsin-Chu City (TW)

(72) Inventors: Kuan-Liang Liu, Hsinchu County (TW); Chung-Yi Chiu, Tainan City (TW)

(73) Assignee: UNITED MICROELECTRONICS CORP., Hsin-Chu City (TW)

(21) Appl. No.: 18/829,176

(22) Filed: Sep. 9, 2024

(30) Foreign Application Priority Data
Aug. 5, 2024 (CN) 202411062029.2

(51) Int. Cl. H01L 29/78; H01L 21/28; H01L 29/423; H01L 29/49; H01L 29/66

(52) U.S. Cl. CPC H10D 30/65; H01L 21/28026; H10D 30/0281; H10D 64/518; H10D 64/667

(57) ABSTRACT

An LDMOS includes a substrate. A lateral direction is parallel to a top surface of the substrate, and a metal gate is disposed on the substrate. The metal gate includes a first side, a second side and a bottom. The first side and the second side are opposite to each other. A source is disposed in the substrate and at the first side, and a drain is disposed in the substrate at the second side. A composite structure covers the first side, the second side and the bottom. The composite structure extends along the lateral direction from the second side to the drain. The composite structure includes a high dielectric material layer, a first work function layer and a second work function layer.

### BACKGROUND OF THE INVENTION

### 1. Field of the Invention

The present invention relates to a laterally diffused metal oxide semiconductor (LDMOS), and particularly to an LDMOS using a work function layer as a field plate and a fabricating method of the same.

### 2. Description of the Prior Art

LDMOS has the characteristics of high breakdown voltage and compatibility with complementary metal oxide semiconductor technology in low voltage devices. Therefore, LDMOS is used in many applications, such as for mobile phones, ADSL drivers, LED displays, LCD display drivers, high power amplifiers for wireless base stations, and other power management. LDMOS devices typically rely on forming insulating regions, such as LOCOS regions or STI regions, to handle the high drain voltages that are applied when the LDMOS device is biased.

However, the LOCOS regions will make the thickness of a metal gate not uniformed. Therefore, problems occur during the planarization of the metal gate.

### SUMMARY OF THE INVENTION

In view of this, the present invention provides a fabricating method of an LDMOS to solve the above problems.

According to a preferred embodiment of the present invention, an LDMOS includes a substrate, wherein a lateral direction is parallel to a top surface of the substrate. A metal gate is disposed on the substrate, wherein the metal gate includes a first side, a second side and a bottom, and the first side is opposite to the second side. A source is disposed in the substrate and at the first side. A drain is disposed in the substrate at the second side. A composite structure covers the first side, the second side and the bottom, wherein the composite structure extends along the lateral direction from the second side to the drain, and the composite structure includes a high dielectric material layer, a first work function layer and a second work function layer.

According to another preferred embodiment of the present invention, a fabricating method of an LDMOS includes providing a substrate, wherein a dielectric layer covers the substrate, a dummy gate is disposed on the substrate, and a gate dielectric layer is disposed between the substrate and the dummy gate. Then, the dummy gate is removed to form a recess in the dielectric layer. Later, a composite structure is formed to fill the recess and cover the dielectric layer, wherein the composite structure includes a high dielectric material layer, a first work function layer and a second work function layer stacked sequentially from bottom to top. After that, a metal gate is formed to be disposed in the recess, wherein two spacers are respectively disposed at a first side and a second side of the metal gate, and the first side and the second side are opposite to each other. Next, a cap layer is formed to cover the metal gate and the composite structure. Then, a mask layer is formed to cover the metal gate and part of the composite structure at the second side. Subsequently, the composite structure not covered by the mask layer is removed. Finally, the mask layer is completely removed.

According to another preferred embodiment of the present invention, a fabricating method of an LDMOS includes providing a substrate, wherein a dielectric layer covers the substrate, a dummy gate is disposed on the substrate, and a gate dielectric layer is disposed between the substrate and the dummy gate. Next, a mask layer is formed to cover the dummy gate and the dielectric layer disposed at one side of the dummy gate. Later, part of the dielectric layer not covered by the mask layer and disposed at the other side of the dummy gate is removed to form a first recess in the dielectric layer. After that, the mask layer is completely removed. Subsequently, the dummy gate is removed to form a second recess in the dielectric layer. Then, a composite structure is formed to cover the first recess, the second recess and the dielectric layer, wherein the composite structure includes a high dielectric material layer, a first work function layer and a second work function layer stacked sequentially from bottom to top. Next, a metal material layer is formed to cover the composite structure. Finally, the metal material layer disposed outside of the second recess is removed, and the composite structure disposed outside of the first recess and the second recess is removed, wherein the metal material layer which remains serves as a metal gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 depict a fabricating method of an LDMOS according to a first preferred embodiment of the present invention, wherein;

FIG. 2 is a fabricating stage in continuous of FIG. 1;

FIG. 3 is a fabricating stage in continuous of FIG. 2;

FIG. 4 is a fabricating stage in continuous of FIG. 3;

FIG. 5 is a fabricating stage in continuous of FIG. 4; and

FIG. 6 is a fabricating stage in continuous of FIG. 5.

FIG. 7 to FIG. 11 depict a fabricating method of an LDMOS according to a second preferred embodiment of the present invention, wherein:

FIG. 8 is a fabricating stage in continuous of FIG. 7;

FIG. 9 is a fabricating stage in continuous of FIG. 8;

FIG. 10 is a fabricating stage in continuous of FIG. 9; and

FIG. 11 is a fabricating stage in continuous of FIG. 10.

FIG. 12 depicts an LDMOS according to a third preferred embodiment of the present invention.

### DETAILED DESCRIPTION

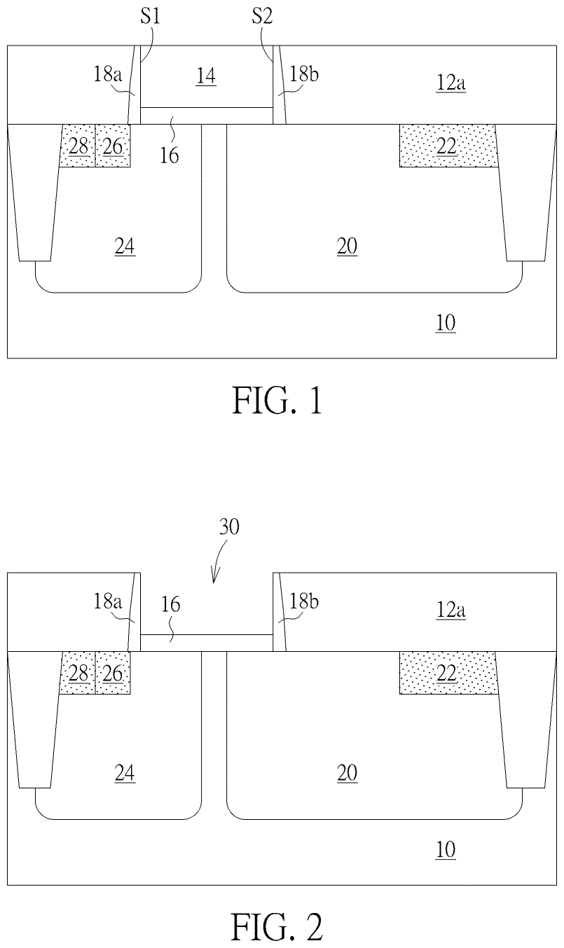

FIG. 1 to FIG. 6 depict a fabricating method of an LDMOS according to a first preferred embodiment of the present invention.

As shown in FIG. 1, a substrate 10 is provided. The substrate 10 includes a silicon substrate, a germanium substrate, a gallium arsenide substrate, a silicon germanium substrate, an indium phosphide substrate, a gallium nitride substrate, a silicon carbide substrate or a silicon on insulator substrate. A dielectric layer 12a covers the substrate 10. The dielectric layer 12a includes an insulating material, such as silicon oxide, silicon nitride, silicon nitride carbide, silicon oxynitride or silicon carbon oxynitride, etc. In this embodiment, the dielectric layer 12a is a single layer made of insulating material. The dummy gate 14 is disposed on the substrate 10. The dummy gate 14 is preferably made of polysilicon. A gate dielectric layer 16 is disposed between the substrate 10 and the dummy gate 14. Two spacers 18a/18b are respectively disposed at a first side S1 and a second side S2 of the dummy gate 14. The first side S1 and the second side S2 are opposite to each other. A drift region 20 is disposed in the substrate 10 at the second side S2 of the dummy gate 14. A drain 22 is disposed in the drift region 20. The body region 24 is disposed in the substrate 10 at the first side S1 of the dummy gate 14. A source 26 is disposed in body region 24. A doped region 28 is disposed at one side of the source 26. The drain 22, the source 26, the drift region 20, the body region 24 and the doped region 28 are preferably formed by implanting dopants into the substrate 10.

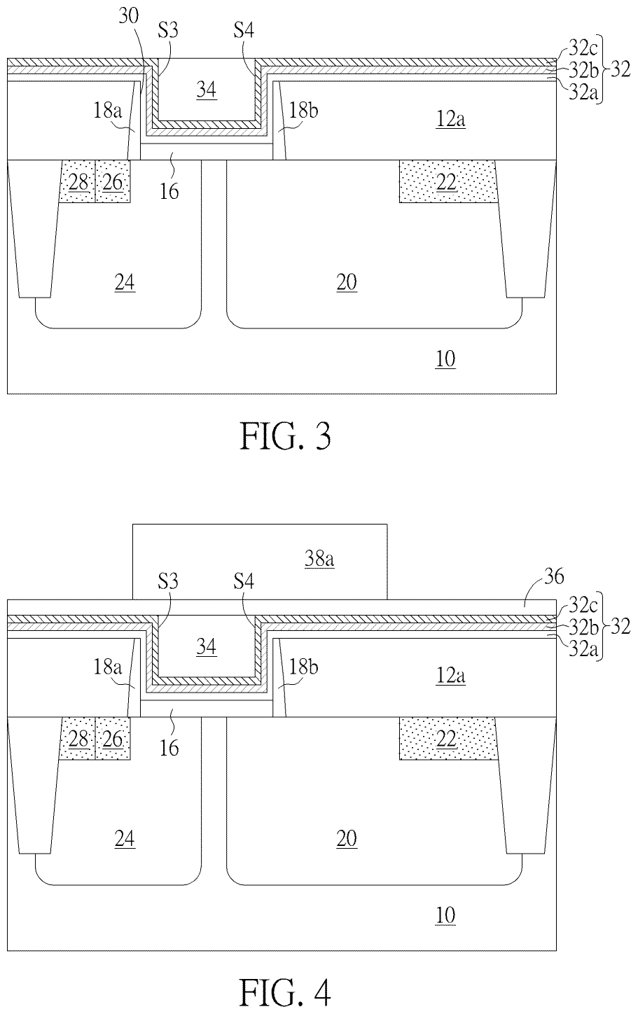

As shown in FIG. 2, the dummy gate 14 is removed to form a recess 30 in dielectric layer 12a. As shown in FIG. 3, a composite structure 32 is formed to fill the recess 30 and cover the dielectric layer 12a. The composite structure 32 includes a high dielectric material layer 32a, a first work function layer 32b and a second work function layer 32c stacked in sequence from bottom to top. In details, the manufacturing method of the composite structure 32 includes forming a high dielectric material layer 32a to conformally cover the dielectric layer 12a, the recess 30, and the spacers 18a/18b. Later, a first work function layer 32b is formed to cover the high dielectric material layer 32a conformally. Next, a second work function layer 32c is formed to cover the first work function layer 32b conformally. After the composite structure 32 is formed, a metal material layer is formed to cover the composite structure 32 and fill the recess 30. After that, the metal material layer is planarized to make the top surface of the remaining metal material layer is aligned with the top surface of the composite structure 32. Now, the remaining metal material layer serves as a metal gate 34. Like the dummy gate 14, the metal gate 34 also has a first side S3 and a second side S4.

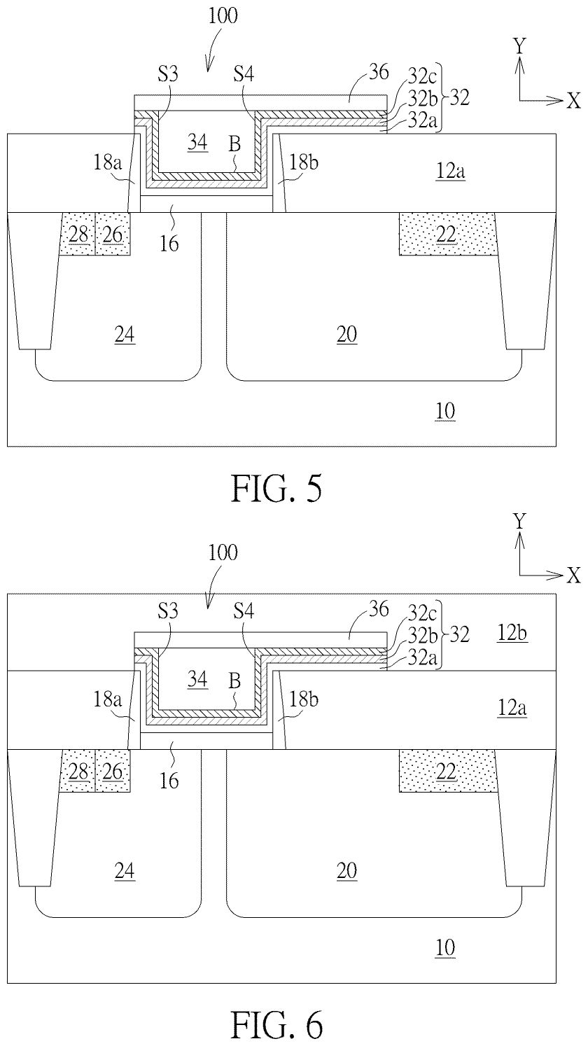

As shown in FIG. 4, a cap layer 36 is formed to cover the metal gate 34 and the composite structure 32. Next, a mask layer 38a is formed to cover the metal gate 34 entirely and to cover part of the composite structure 32 which extends to drain 22 and disposed at the second side S4. The mask layer 38a is preferably photoresist. Then, the cap layer 36 and the composite structure 32 which are not covered by the mask layer 38a are removed by taking the mask layer 38a as a mask. As shown in FIG. 5, the mask layer 38a is removed. Now, the LDMOS 100 of the present invention is completed. In the LDMOS 100, the composite structure 32 located at the second side S4 of the metal gate 34 and extending toward the drain 22 serves as a field plate. The composite structure 32 serving as the field plate protrudes from the top surface of the dielectric layer 12a. As shown in FIG. 6, a dielectric layer 12b is formed to cover the LDMOS 100 and the dielectric layer 12a. The dielectric layer 12a and the dielectric layer 12b respectively include an insulating material such as silicon oxide, silicon nitride, silicon nitride carbide, silicon oxynitride or silicon carbon oxynitride, etc.

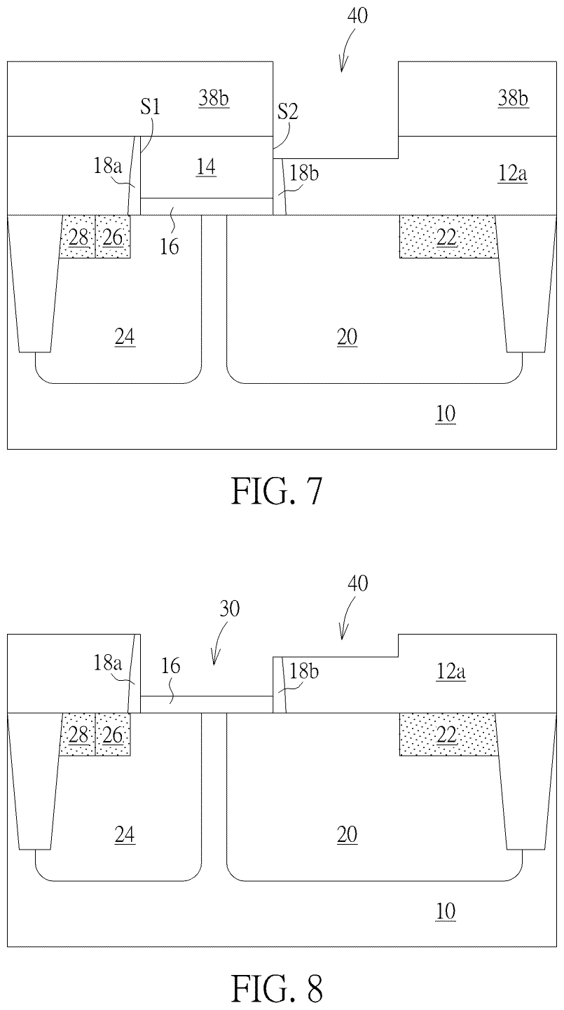

FIG. 7 to FIG. 11 depict a fabricating method of an LDMOS according to a second preferred embodiment of the present invention, wherein elements which are substantially the same as those in the first preferred embodiment of are denoted by the same reference numerals; an accompanying explanation is therefore omitted.

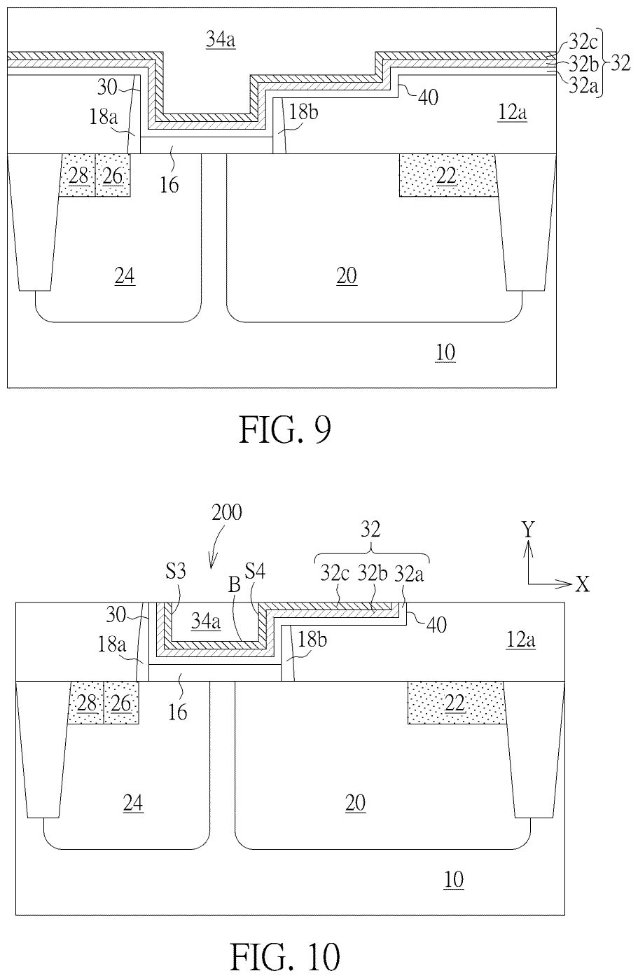

FIG. 7 depicts fabricating steps in continuous of FIG. 1. As shown in FIG. 7, a mask layer 38b is formed to cover the dummy gate 14 and the dielectric layer 12a disposed at the first side S1 of the dummy gate 14. Therefore, the spacer 18b at the second side S2 of the dummy gate 14 and the dielectric layer 12a at the second side S2 are exposed through the mask layer 38b. The mask layer 38b is preferably photoresist. Then, part of the spacer 18b and the dielectric layer 12a are etched to form a recess 40 in the dielectric layer 12a by taking the mask layer 38b as a mask. As shown in FIG. 8, after the mask layer 38b is completely removed, the dummy gate 14 is removed to form a recess 30 in dielectric layer 12a. As shown in FIG. 9, the composite structure 32 is formed to cover the recess 40, the recess 30 and the dielectric layer 12a conformally. The composite structure 32 includes a high dielectric material layer 32a, a first work function layer 32b and a second work function layer 32c stacked in sequence from bottom to top. In details, after the high dielectric material layer 32a is formed, the first work function layer 32b is then formed. Later, the second work function layer 32c is formed. Next, a metal material layer 34a is formed to cover the composite structure 32 and fill the recess 30 and the recess 40, and the metal material layer 34a covers the dielectric layer 12a.

As shown in FIG. 10, the metal material layer 34a outside of the recess 30 is removed and the composite structure 32 outside of the recess 30 and the recess 40 is removed. The remaining metal material layer 34a serves as a metal gate 34. The remaining composite structure 32 in the recess 40 serves as a field plate. That is, the composite structure 32 extending from the second side S4 to the drain 22 serves as the field plate. The top surface of the composite structure 32 which extends toward the drain 22 and which is disposed at the second side S4 is aligned with the dielectric layer 12a. The top surface of the metal gate 34 is aligned with the dielectric layer 12a. Now, an LDMOS 200 of the present invention is completed. As shown in FIG. 11, a dielectric layer 12b is formed to cover the LDMOS 200.

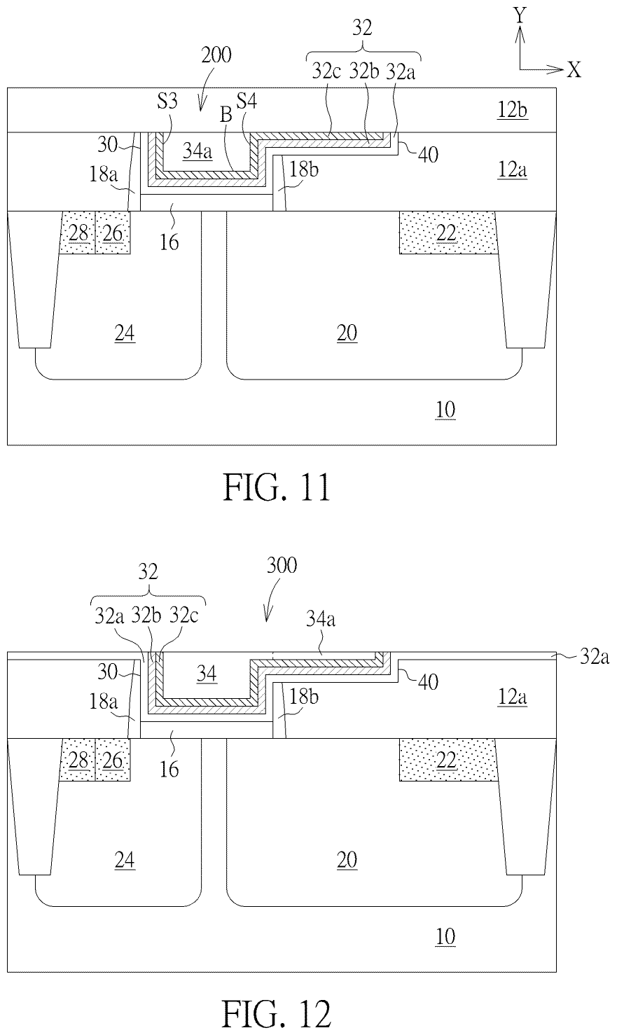

According to another preferred embodiment of the present invention, continuing from FIG. 9, as shown in FIG. 12, the metal material layer 34a, the first work function layer 32b and the second work function layer 32c outside of the recess 30 and the recess 40 are removed by taking the high dielectric material layer 32a as a stop layer. The remaining metal material layer 34a disposed in the recess 30 serves as the metal gate 34. In other words, the metal material layer 34a with the gate dielectric layer 16 underneath serves as the metal gate 34. The remaining composite structure 32 and the metal material layer 34a in the recess 40 serve as the field plate. The high dielectric material layer 32a covers the dielectric layer 12a outside of the recess 30 and the recess 40. Now, an LDMOS 300 is completed.

As shown in FIG. 5, the LDMOS 100 of the present invention includes a substrate 10. A horizontal direction X is parallel to the top surface of the substrate 10. A vertical direction Y is perpendicular to the top surface of the substrate 10. A metal gate 34 is disposed on the substrate 10. The metal gate 34 includes a first side S3, a second side S4 and a bottom B. The first side S3 and the second side S4 are opposite. The two spacers 18a/18b are respectively disposed at the first side S3 and the second side S4 of the metal gate 34. A gate dielectric layer 16 is disposed between the metal gate 34 and the substrate 10. The gate dielectric layer 16 contacts substrate 10. The gate dielectric layer 16 includes insulating materials such as silicon oxide, silicon nitride, or silicon oxynitride.

A drift region 20 is disposed in the substrate 10 at the second side S4 of the metal gate 34. Part of the drift region 20 extends below the metal gate 34. A drain 22 is disposed in the drift region 20. A body region 24 is disposed in the substrate 10 at the first side S3 of the metal gate 34. Part of the body region 24 extends below the metal gate 34. A source 26 is disposed in body region 24. A doped region 28 is disposed at one side of the source 26 and is farther away from the metal gate 34 than the source 26. A composite structure 32 covers and contacts the first side S3, the second side S4 and the bottom B of the metal gate 34. The composite structure 32 extends along the horizontal direction X from the second side S4 to the drain 22. The composite structure 32 extending from the second side S4 to the drain 22 serves as a field plate. Moreover, the composite structure 32 extending from the second side S4 to the drain 22 does not overlap the metal gate 34 in the vertical direction Y. The composite structure 32 includes a high dielectric material layer 32a, a first work function layer 32b and a second work function layer 32c. The first work function layer 32b is sandwiched between the high dielectric material layer 32a and the second work function layer 32c. The second work function layer 32c contacts the second side S4, the first side S3 and the bottom B of the metal gate 34. The high dielectric material layer 32a contacts the spacers 18a/18b and the gate dielectric layer 16. A cap layer 36 covers and contacts the metal gate 34 and the composite structure 32.

The spacers 18a/18b and the cap layer 36 are preferably silicon nitride or silicon oxynitride. The high dielectric material layer 32a includes HfO₂, HfSiO₄, HfSiON, Al₂O₃, La₂O₃, Ta₂O₅, Y₂O₃, ZrO₂, SrTiO₃, ZrSiO₄, HfZrO₄, SrBi₂Ta₂O₉ (SBT), PbZrₓTi₁₋ₓO₃ (PZT) or BaₓSr₁₋ₓTiO₃ (BST).

In addition, the drain 22, the source 26 and the drift region 20 are first conductive type. The body region 24 and the doped region 28 are second conductive type. In this embodiment, the first conductive type is N-type, and the second conductive type is P-type. However, in different embodiments, the first conductive type may be P type, and the second conductive type may be N type. If the first conductive type is N-type, the LDMOS 100, the LDMOS 200 and the LDMOS 300 are N-type semiconductors. When the first conductive type is P-type, the LDMOS 100, the LDMOS 200 and the LDMOS 300 are P-type semiconductors.

The first work function layer 32b may be an N-type work function layer or a P-type work function layer. The second work function layer 32c may be As long as the first work function layer 32b and the second work function layer 32c respectively belong to different conductive types.

The N-type work function layer includes Hf, Ti, Zr, Cd, La, Yb, Al, Ce, Eu, Li, Pb, Tb, Bi, In, Lu, Nb, Sm, V, Ga, Mg, Gd, Y, TiAl, ZrAl, WAl alloy, TaAl alloy or HfAl alloy. The P-type work function layer includes Pt, Rh, Ir, Ru, Cu, Os, Be, Co, Pd, Te, Cr, Ni, TiN, TiC, TaN, TaC, WC or TiAlN.

In a first preferred embodiment, the top surface of the spacer 18a and the top surface spacer 18b are aligned with each other. Part of the composite structure 32 covers the top surface of the spacer 18a and the top surface spacer 18b. The top surface of the metal gate 34 is higher than the top surfaces of the spacers 18a/18b.

As shown in FIG. 10, the difference between the second preferred embodiment and the first preferred embodiment is that in the second preferred embodiment, the top surface of the spacer 18b disposed at the second side S4 is lower than the top surface of the spacer 18a disposed at the first side S3. Furthermore, the composite structure 32 does not cover the top surface of the spacer 18a disposed at the first side S4. Furthermore, the top surface of the metal gate 34 is aligned with the top surface of the spacer 18a disposed at the first side S3, but is higher than the top surface of the spacer 18b disposed at the second side S4. Other materials and positions of elements in the second preferred embodiment are the same as those in the first preferred embodiment, and the descriptions are omitted here.

As shown in FIG. 10 and FIG. 12, the difference between the second preferred embodiment and the third preferred embodiment is that in the second preferred embodiment, only the composite structure 32 extends from the second side S4 to the drain 22 serves as a field plate. As show in FIG. 12, in the third preferred embodiment, the field plate includes a composite structure 32 extending from the second side S4 to the drain 22 and a metal material layer 34a connected to the metal gate 34. The metal gate 34 and the metal material layer 34a are separated by dotted lines.

Traditional LDMOS does not have the first work function layer and the second work function layer extending toward the drain. Therefore, the electric field density at the bottom corner of the metal gate is too high. Unexpected current conduction is easily occurred between the bottom corner of the metal gate and the drift region.

The first work function layer and the second work function layer extend toward the drain are used as a field plate in the present invention. The field plate covers the substrate between the metal gate and drain. In this way, the electric field concentrated at the bottom corner of the metal gate can be distributed towards the drain, and the breakdown voltage of LDMOS can be increased.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A laterally diffused metal oxide semiconductor (LDMOS), comprising:
a substrate, wherein a lateral direction is parallel to a top surface of the substrate;
a metal gate disposed on the substrate, wherein the metal gate comprises a first side, a second side and a bottom, and the first side is opposite to the second side;
a source disposed in the substrate and at the first side;
a drain disposed in the substrate at the second side;
a composite structure covering the first side, the second side and the bottom, wherein the composite structure extends along the lateral direction from the second side to the drain, and the composite structure comprises a high dielectric material layer, a first work function layer and a second work function layer.

2. The LDMOS of claim 1, wherein the first work function layer is disposed between the high dielectric material layer and the second work function layer.

3. The LDMOS of claim 1, wherein the second work function layer contacts the first side, the second side and the bottom.

4. The LDMOS of claim 1, further comprising:
two spacers respectively disposed at the first side and the second side of the metal gate, wherein a top surface of each of the two spacers is aligned with each other, and the composite structure covers the top surface of each of the two spacers;
a gate dielectric layer disposed below the bottom of the metal gate;
a drift region disposed in the substrate at the second side of the metal gate, wherein the drain is disposed in the drift region; and
a body region disposed in the substrate at the first side of the metal gate, wherein the source is disposed in the body region.

5. The LDMOS of claim 1, further comprising:
two spacers respectively disposed at the first side and the second side of the metal gate, wherein a top surface of the spacer disposed at the second side is lower than a top surface of the spacer disposed at the first side, and the composite structure does not cover the top surface of the spacer disposed at the first side
a gate dielectric layer disposed below the bottom of the metal gate;
a drift region disposed in the substrate at the second side of the metal gate, wherein the drain is disposed in the drift region; and
a body region disposed in the substrate at the first side of the metal gate, wherein the source is disposed in the body region.

6. The LDMOS of claim 1, wherein the first work function layer is an N-type work function layer, the second work function layer is a P-type work function layer, the N-type work function layer comprises Hf, Ti, Zr, Cd, La, Yb, Al, Ce, Eu, Li, Pb, Tb, Bi, In, Lu, Nb, Sm, V, Ga, Mg, Gd, Y, TiAl, ZrAl, WAl alloy, TaAl alloy or HfAl alloy, and the P-type work function layer comprises Pt, Rh, Ir, Ru, Cu, Os, Be, Co, Pd, Te, Cr, Ni, TiN, TiC, TaN, TaC, WC or TiAlN.

7. The LDMOS of claim 1, wherein the first work function layer is a P-type work function layer, the second work function layer is an N-type work function layer, the P-type work function layer comprises Pt, Rh, Ir, Ru, Cu, Os, Be, Co, Pd, Te, Cr, Ni, TiN, TiC, TaN, TaC, WC or TiAlN, and the N-type work function layer comprises Hf, Ti, Zr, Cd, La, Yb, Al, Ce, Eu, Li, Pb, Tb, Bi, In, Lu, Nb, Sm, V, Ga, Mg, Gd, Y, TiAl, ZrAl, WAl alloy, TaAl alloy or HfAl alloy.

8. The LDMOS of claim 1, wherein the high dielectric material layer comprises HfO₂, HfSiO₄, HfSiON, Al₂O₃, La₂O₃, Ta₂O₅, Y₂O₃, ZrO₂, SrTiO₃, ZrSiO₄, HfZrO₄, SrBi₂Ta₂O₉ (SBT), PbZrₓTi₁₋ₓO₃ (PZT) or BaₓSr₁₋ₓTiO₃ (BST).

9. The LDMOS of claim 1, wherein the composite structure which extends from the second side toward the drain does not overlap the metal gate.

10. A fabricating method of a laterally diffused metal oxide semiconductor (LDMOS), comprising:
providing a substrate, wherein a dielectric layer covers the substrate, a dummy gate is disposed on the substrate, and a gate dielectric layer is disposed between the substrate and the dummy gate;
removing the dummy gate to form a recess in the dielectric layer;
forming a composite structure to fill the recess and cover the dielectric layer, wherein the composite structure comprises a high dielectric material layer, a first work function layer and a second work function layer stacked sequentially from bottom to top;
forming a metal gate disposed in the recess, wherein two spacers are respectively disposed at a first side and a second side of the metal gate, and the first side and the second side are opposite to each other;
forming a cap layer covering the metal gate and the composite structure;
forming a mask layer to cover the metal gate and part of the composite structure at the second side;
removing the composite structure not covered by the mask layer; and
completely removing the mask layer.

11. The fabricating method of an LDMOS of claim 10, further comprising:
a drift region disposed in the substrate at the second side of the metal gate;
a body region disposed in the substrate at the first side of the metal gate;
a source disposed in the substrate and at the first side, wherein the source is disposed in the body region; and
a drain disposed in the substrate at the second side, wherein the drain is disposed in the drift region.

12. The fabricating method of an LDMOS of claim 10, wherein after removing the composite structure not covered by the mask layer, the composite structure which remains extends along a horizontal direction from the second side to the drain, and the horizontal direction is parallel to a top surface of the substrate, and the composite structure which remains does not overlap the metal gate.

13. The fabricating method of an LDMOS of claim 10, wherein the first work function layer is an N-type work function layer, the second work function layer is a P-type work function layer, the N-type work function layer comprises Hf, Ti, Zr, Cd, La, Yb, Al, Ce, Eu, Li, Pb, Tb, Bi, In, Lu, Nb, Sm, V, Ga, Mg, Gd, Y, TiAl, ZrAl, WAl alloy, TaAl alloy or HfAl alloy, and the P-type work function layer comprises Pt, Rh, Ir, Ru, Cu, Os, Be, Co, Pd, Te, Cr, Ni, TiN, TiC, TaN, TaC, WC or TiAlN.

14. The fabricating method of an LDMOS of claim 10, wherein the first work function layer is a P-type work function layer, the second work function layer is an N-type work function layer, the P-type work function layer comprises Pt, Rh, Ir, Ru, Cu, Os, Be, Co, Pd, Te, Cr, Ni, TiN, TiC, TaN, TaC, WC or TiAlN, and the N-type work function layer comprises Hf, Ti, Zr, Cd, La, Yb, Al, Ce, Eu, Li, Pb, Tb, Bi, In, Lu, Nb, Sm, V, Ga, Mg, Gd, Y, TiAl, ZrAl, WAl alloy, TaAl alloy or HfAl alloy.

15. A fabricating method of a laterally diffused metal oxide semiconductor (LDMOS), comprising:
providing a substrate, wherein a dielectric layer covers the substrate, a dummy gate is disposed on the substrate, and a gate dielectric layer is disposed between the substrate and the dummy gate;
forming a mask layer to cover the dummy gate and the dielectric layer disposed at one side of the dummy gate;
removing part of the dielectric layer not covered by the mask layer and disposed at the other side of the dummy gate to form a first recess in the dielectric layer;
completely removing the mask layer;
removing the dummy gate to form a second recess in the dielectric layer;
forming a composite structure covering the first recess, the second recess and the dielectric layer, wherein the composite structure comprises a high dielectric material layer, a first work function layer and a second work function layer stacked sequentially from bottom to top;
form a metal material layer to cover the composite structure; and
removing the metal material layer disposed outside of the second recess, and removing the composite structure disposed outside of the first recess and the second recess, wherein the metal material layer which remains serves as a metal gate.

16. The fabricating method of an LDMOS of claim 15, wherein the metal gate comprises a first side and a second side, and the first side is opposite to the second side.

17. The fabricating method of an LDMOS of claim 16, further comprising:
a drift region disposed in the substrate at the second side of the metal gate;
a body region disposed in the substrate at the first side of the metal gate;
a source disposed in the substrate and at the first side, wherein the source is disposed in the body region; and
a drain disposed in the substrate at the second side, wherein the drain is disposed in the drift region.

18. The fabricating method of an LDMOS of claim 17, wherein after removing the metal gate and the composite structure disposed outside the first recess and the second recess, the composite structure which remains extends along a horizontal direction from the second side to the drain, and the horizontal direction is parallel to a top surface of the substrate, and the composite structure which remains does not overlap the metal gate.

19. The fabricating method of an LDMOS of claim 15, wherein the first work function layer is an N-type work function layer, the second work function layer is a P-type work function layer, the N-type work function layer comprises Hf, Ti, Zr, Cd, La, Yb, Al, Ce, Eu, Li, Pb, Tb, Bi, In, Lu, Nb, Sm, V, Ga, Mg, Gd, Y, TiAl, ZrAl, WAl alloy, TaAl alloy or HfAl alloy, and the P-type work function layer comprises Pt, Rh, Ir, Ru, Cu, Os, Be, Co, Pd, Te, Cr, Ni, TiN, TiC, TaN, TaC, WC or TiAlN.

20. The fabricating method of an LDMOS of claim 15, wherein the first work function layer is a P-type work function layer, the second work function layer is an N-type work function layer, the P-type work function layer comprises Pt, Rh, Ir, Ru, Cu, Os, Be, Co, Pd, Te, Cr, Ni, TiN, TiC, TaN, TaC, WC or TiAlN, and the N-type work function layer comprises Hf, Ti, Zr, Cd, La, Yb, Al, Ce, Eu, Li, Pb, Tb, Bi, In, Lu, Nb, Sm, V, Ga, Mg, Gd, Y, TiAl, ZrAl, WAl alloy, TaAl alloy or HfAl alloy.
